(19) United States
(12) Patent Application Publication
(10) Pub. No.: US 2025/0132271 A1
(43) Pub. Date: Apr. 24, 2025

(54) SEMICONDUCTOR PACKAGE

(71) Applicant: SAMSUNG ELECTRONICS CO., LTD., Suwon-si (KR)

(72) Inventors: Kyojin Hwang, Suwon-si (KR); Junso Pak, Suwon-si (KR); Heeseok Lee, Suwon-si (KR)

(21) Appl. No.: 18/912,124

(22) Filed: Oct. 10, 2024

(30) Foreign Application Priority Data
Oct. 24, 2023 (KR) 10-2023-0143113

(51) Int. Cl. H01L 23/64; H01L 23/498; H01L 25/16; H05K 1/11; H05K 1/18

(52) U.S. Cl. CPC H01L 23/642; H01L 23/49822; H01L 23/49838; H01L 25/16; H05K 1/116; H05K 1/181; H05K 1/185; H10D 1/68; H05K 2201/10015

(57) ABSTRACT

A semiconductor package includes a printed circuit board including a circuit pattern and a silicon capacitor connected to the circuit pattern, a semiconductor chip mounted on the printed circuit board, and an external connection terminal attached below the printed circuit board, wherein the silicon capacitor is a stacked structure of a plurality of substrate structures, each of the plurality of substrate structures includes a silicon substrate, a capacitor structure, a via electrode penetrating through the silicon substrate around the capacitor structure, an upper bump pad disposed on top of the via electrode, and a lower bump pad disposed below the via electrode, and, in the plurality of substrate structures, neighboring silicon substrates are bonded to each other through the upper bump pad and the lower bump pad facing each other.

### CROSS-REFERENCE TO RELATED APPLICATION

This application claims priority to Korean Patent Application No. 10-2023-0143113, filed in the Korean Intellectual Property Office on Oct. 24, 2023, the disclosure of which is incorporated by reference herein in its entirety.

### BACKGROUND

Recently, the electronic products market has experienced a dramatic increase in the demand for portable electronic devices, and thus, miniaturization and weight reduction of electronic components mounted on these portable electronic devices are continuously demanded. Although the overall thickness of semiconductor packages is decreasing to miniaturize and reduce the weight of electronic components, the demand for increased memory capacity is continuously increasing. Therefore, various structures have been applied to efficiently arrange semiconductor chips, active devices, and passive devices within the limited structure of a semiconductor package.

### SUMMARY

In general, in some aspects, the present disclosure is directed toward a semiconductor package having an increased degree of freedom in circuit design while allowing the increase of capacitance by using a stacked silicon capacitor having solder bump pads on both the top surface and the bottom surface.

According to some aspects of the present disclosure, a semiconductor package includes a printed circuit board including a circuit pattern and a silicon capacitor connected to the circuit pattern, a semiconductor chip mounted on the printed circuit board, and an external connection terminal attached below the printed circuit board, wherein the silicon capacitor is a stacked structure of a plurality of substrate structures, each of the plurality of substrate structures includes a silicon substrate, a capacitor structure, a via electrode penetrating through the silicon substrate around the capacitor structure, an upper bump pad disposed on top of the via electrode, and a lower bump pad disposed below the via electrode, wherein, in the plurality of substrate structures, neighboring silicon substrates are bonded to each other through the upper bump pad and the lower bump pad facing each other.

According to some aspects of the present disclosure, a semiconductor package includes a redistribution structure including a redistribution layer and a silicon capacitor connected to the redistribution layer, a semiconductor chip mounted on the redistribution structure, and an external connection terminal attached below the redistribution structure, wherein the silicon capacitor is a stacked structure of a plurality of substrate structures, each of the plurality of substrate structures includes a silicon substrate, a capacitor structure, a via electrode penetrating through the silicon substrate around the capacitor structure, an upper bump pad disposed on top of the via electrode, and a lower bump pad disposed below the via electrode, wherein, in the plurality of substrate structures, neighboring silicon substrates are bonded to each other through the upper bump pad and the lower bump pad facing each other.

According to some aspects of the present disclosure, a semiconductor package includes a silicon capacitor that is a stacked structure in which N (N is an integer greater than or equal to 2) substrate structures are electrically connected to each other, a semiconductor chip is mounted on a wiring structure including at least one silicon capacitor, and each of the N substrate structures includes a silicon substrate having a first surface and a second surface facing each other, a capacitor structure disposed on the first surface of the silicon substrate, an electrode line disposed on top of the capacitor structure, a via electrode penetrating through the silicon substrate around the capacitor structure, a first insulation layer disposed on the first surface of the silicon substrate and surrounds a first bump pad disposed at one end of the via electrode, and a second insulation layer disposed on the second surface of the silicon substrate and surrounds a second bump pad disposed at the other end of the via electrode.

### BRIEF DESCRIPTION OF THE DRAWINGS

Exemplary implementations will be more clearly understood from the following description, taken in conjunctions with the accompanying drawings.

FIG. 1 is a cross-sectional view showing main components of an example of a semiconductor package according to some implementations.

FIG. 2 is an enlarged plan view of an example of a silicon capacitor of FIG. 1 according to some implementations.

FIG. 3 is a cross-sectional view taken along a line A-A′ of FIG. 2 according to some implementations.

FIG. 4 is a cross-sectional view showing main components of an example of a semiconductor package according to some implementations.

FIG. 5 is an enlarged plan view of an examples of a silicon capacitor of FIG. 4 according to some implementations.

FIG. 6 is a cross-sectional view taken along a line B-B′ of FIG. 5 according to some implementations.

FIG. 7 is a flowchart of an example of a method of manufacturing a silicon capacitor according to some implementations.

FIGS. 8 to 12 are cross-sectional views showing an example of a method of manufacturing a silicon capacitor according to some implementations.

FIG. 13 is a flowchart of an example of a method of manufacturing a semiconductor package according to some implementations.

FIGS. 14 to 18 are cross-sectional views showing an example of a method of manufacturing a semiconductor package according to some implementations.

FIG. 19 is a flowchart of an example of a method of manufacturing a semiconductor package according to some implementations.

FIGS. 20 to 27 are cross-sectional views showing an example of a method of manufacturing a semiconductor package according to some implementations.

FIG. 28 is a diagram schematically showing an example of a configuration of a semiconductor package according to some implementations.

### DETAILED DESCRIPTION

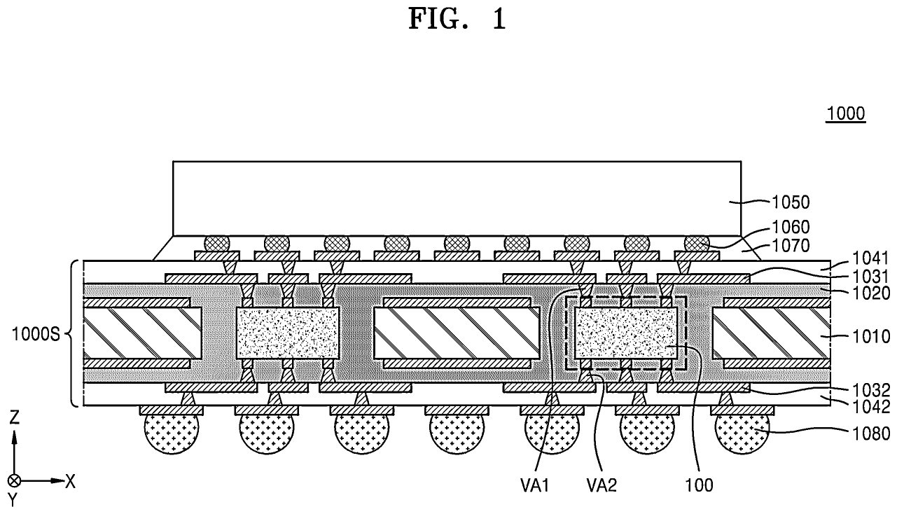

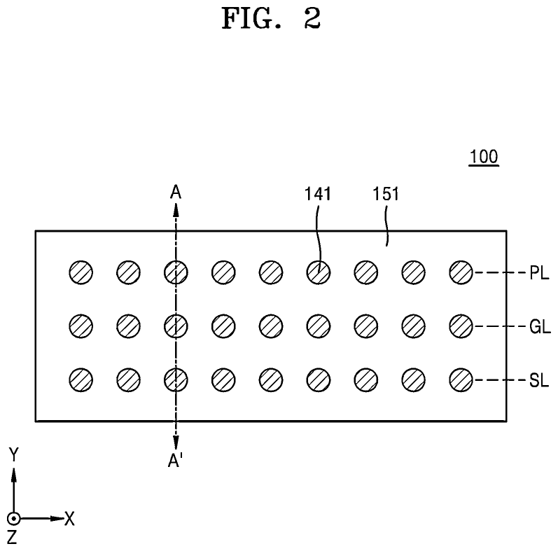

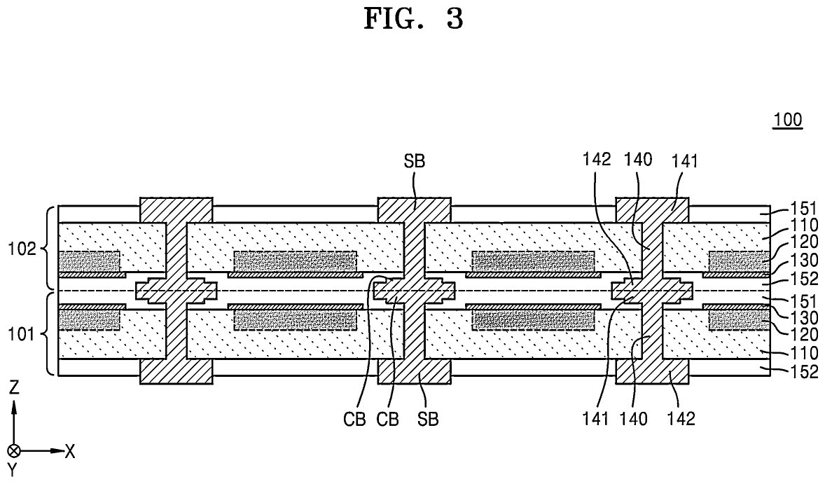

FIG. 1 is a cross-sectional view showing main components of an example of a semiconductor package according to some implementations. FIG. 2 is an enlarged plan view of an example of a silicon capacitor of FIG. 1 according to some implementations. FIG. 3 is a cross-sectional view taken along a line A-A′ of FIG. 2 according to some implementations.

In FIGS. 1 to 3, a semiconductor package 1000 includes a package substrate 1000S on which a silicon capacitor 100 is disposed, a semiconductor chip 1050 mounted on the package substrate 1000S, and an external connection terminal 1080 attached below the package substrate 1000S. The package substrate 1000S is a support substrate and may include a core base 1010, a core insulation layer 1020, an upper protective layer 1041, and a lower protective layer 1042. The package substrate 1000S may be formed based on a printed circuit board (PCB), a wafer substrate, a ceramic substrate, a glass substrate, etc.

In some implementations, the package substrate 1000S may be a PCB. For example, when the package substrate 1000S is a PCB, the core base 1010 may be formed by compressing a polymer material such as a thermosetting resin, an epoxy-based resin such as Flame Retardant 4 (FR4), Bismalcimide Triazine (BT), or Ajinomoto Build-up Film (ABF), or a phenol resin to a certain thickness to form a thin-film, coating both surfaces of the thin-film with copper foil, and forming a circuit pattern, which is a path for transmitting electrical signals, thereon through patterning. Except for the circuit pattern, solder resist may be applied to the entire top surface and the entire bottom surfaces of the core insulation layer 1020, thereby forming the upper protective layer 1041 and the lower protective layer 1042.

According to some implementations, the package substrate 1000S may include a single-layer PCB in which the circuit pattern is formed on only one surface and a double-layer PCB in which the circuit pattern is formed on both surfaces. Also, three or more copper foil layers may be formed by using an insulation material such as prepreg, and the circuit pattern may be formed according to the number of copper foil layers, thereby forming a PCB having a multi-layered structure. However, the package substrate 1000S is not limited to the structure or the material described above.

In the package substrate 1000S, the silicon capacitor 100 may be placed in a cavity of the core base 1010, an upper circuit pattern 1031 may be formed above the core base 1010, and a lower circuit pattern 1032 may be formed below the core base 1010. Also, the external connection terminal 1080 may be attached below the lower circuit pattern 1032. For example, the semiconductor package 1000 may be mounted by being electrically connected to a module board or a system board of an electronic device through the external connection terminal 1080.

Although the package substrate 1000S is shown to include two silicon capacitors 100 embedded in the cavity of the core base 1010, the package substrate 1000S is not limited thereto, and the silicon capacitors 100 may be embedded at regular intervals in the package substrate 1000S. A cavity may be formed in the core base 1010 in the form of a via hole, and the cavity may be formed through laser processing or drilling using CNC. In this case, the cavity may be formed to be equal to or larger than the width of the silicon capacitor 100 inserted therein. In the package substrate 1000S, the core base 1010 may include an insulation material. However, the core base 1010 may also include a metal material such as aluminum to improve heat dissipation efficiency.

The core insulation layer 1020 may be disposed on each of the top surface and the bottom surface of the core base 1010 in which the silicon capacitor 100 is embedded. The core insulation layer 1020 may include an insulation material. An upper vertical via VA1 and a lower vertical via VA2 electrically connected to the upper circuit pattern 1031 and the lower circuit pattern 1032 may be arranged in the core insulation layer 1020. Also, the upper vertical via VA1 and the lower vertical via VA2 may be connected to the top surface and the bottom surface of the silicon capacitor 100 embedded in the core base 1010 and electrically interconnect the upper circuit pattern 1031 and the lower circuit pattern 1032.

In some implementations, in the semiconductor package 1000, the upper circuit pattern 1031 and the lower circuit pattern 1032 may electrically interconnect the semiconductor chip 1050 and the external connection terminal 1080 by using wires in the silicon capacitor 100. Detailed descriptions thereof will be given later.

The semiconductor chip 1050 included in the semiconductor package 1000 may be a logic chip or a memory chip. In some implementations, the semiconductor chip 1050 may have a chiplet structure including a plurality of semiconductors. The memory chip may be, for example, a volatile memory chip such as dynamic random access memory (DRAM) or static random access memory (SRAM) or a non-volatile memory chip such as phase-change random access memory (PRAM), magneto-resistive random access memory (MRAM), ferroelectric random access memory (FeRAM), or resistive random access memory (RRAM). Also, the logic chip may be, for example, a microprocessor, an analog device, or a digital signal processor.

The internal connection terminal 1060 may be disposed between the semiconductor chip 1050 and the package substrate 1000S. For example, the internal connection terminal 1060 may be a solder ball or a micro bump. In other words, the semiconductor chip 1050 and the upper circuit pattern 1031 of the package substrate 1000S may be electrically connected to each other through the internal connection terminal 1060. The internal connection terminal 1060 may include, for example, copper (Cu), aluminum (Al), silver (Ag), tin (Tin), gold (Au), or solder. However, the inventive concept is not limited thereto.

An underfill 1070 may be formed between the semiconductor chip 1050 and the package substrate 1000S. A gap may be formed between the semiconductor chip 1050 and the package substrate 1000S. Since such a gap may cause problems in the reliability of the connection between the semiconductor chip 1050 and the package substrate 1000S, the underfill 1070 is injected to reinforce the connection. In some cases, the underfill 1070 may be omitted, and a molded underfill (MUF) process may be used instead.

In the semiconductor package 1000, the silicon capacitor 100 may have a stacked structure in which N (N is an integer equal to or greater than 2) substrate structures are electrically connected to each other. For example, the silicon capacitor 100 may have a stacked structure of two substrate structures 101 and 102. However, the number of the plurality of substrate structures 101 and 102 is not limited thereto.

The plurality of substrate structures 101 and 102 may each include a silicon substrate 110, a capacitor structure 120, a via electrode 140 extending through the silicon substrate 110 around (or between) the capacitor structure 120, an upper bump pad 141 disposed on the via electrode 140, and a lower bump pad 142 disposed below the via electrode 140. An upper insulation layer 151 may be disposed around the upper bump pad 141, and a lower insulation layer 152 may be disposed around the lower bump pad 142.

According to some implementations, in the plurality of substrate structures 101 and 102, the upper bump pad 141 and the lower bump pad 142 of neighboring silicon substrates 110 facing each other may be bonded to each other, e.g., through direct bonding. For example, in the silicon capacitor 100, the upper bump pad 141 located at the top of the plurality of substrate structures 101 and 102 and the lower bump pad 142 located at the bottom of the plurality of substrate structures 101 and 102 may be solder bump pads SB, and the remaining upper bump pads 141 and the remaining lower bump pads 142 may be copper bump pads CB. In other words, the remaining upper bump pads 141 and the remaining lower bump pads 142 may be bonded to each other, e.g., through copper-to-copper (Cu-to-Cu) direct bonding.

Additionally, the via electrode 140 may be disposed on each of the silicon substrates 110, and the via electrode 140 may be positioned between capacitor structures 120. Here, the via electrode 140 may perform the function of at least one from among a power line PL, a ground line GL, and a signal line SL. Accordingly, the upper circuit pattern 1031 and the lower circuit pattern 1032 may be electrically connected to each other through the upper vertical via VA1 contacting the top surface of the silicon capacitor 100 and the lower vertical via VA2 contacting the bottom surface of the silicon capacitor 100.

According to some implementations, the upper vertical via VA1 may be in direct contact with an uppermost solder bump pad SB, and the lower vertical via VA2 may be in direct contact with a lowermost solder bump pad SB, and thus the upper vertical via VA1 and the lower vertical via VA2 may be electrically connected to the via electrode 140.

According to some implementations, the capacitor structure 120 may be a buried type disposed in the shape of a trench structure inside the silicon substrate 110. According to some implementations, the capacitor structure 120 may be a protruding type disposed in the shape of a pillar structure on top of the silicon substrate 110.

Structurally, the capacitor structure 120 may be disposed adjacent to the top surface of the silicon substrate 110, and the capacitor structures 120 may be arranged in a mirror-symmetrically around the upper insulation layer 151 and the lower insulation layer 152 arranged between the silicon substrates 110 adjacent to each other in the plurality of substrate structures 101 and 102. According to some implementations, the plurality of capacitor structures 120 may be arranged on each of the silicon substrates 110 in horizontal directions (X direction and Y directions). Also, an electrode line 130 may be disposed on the capacitor structure 120. The electrode line 130 may be connected to an upper electrode and a lower electrode constituting the capacitor structure 120.

In some implementations, the semiconductor package 1000 includes a stacked silicon capacitor 100 including the plurality of substrate structures 101 and 102. Accordingly, the silicon capacitor 100 has about twice the electrostatic capacity and lower equivalent series resistance (ESR) characteristic as compared to a typical single-layer silicon capacitor. As such, the present disclosure provides solutions for efficiently arranging various components such as semiconductor chips, active devices, and passive devices within a limited structure of a semiconductor package, which can be designed for portable electronic devices with reduced side and weight while providing increased memory capacity.

Additionally, in some implementations, the semiconductor package 1000 includes the upper circuit pattern 1031 and the lower circuit pattern 1032 that may electrically interconnect the semiconductor chip 1050 and the external connection terminal 1080 by using wires inside the silicon capacitor 100. Accordingly, the degree of freedom in circuit design in the package substrate 1000S may be significantly increased.

In some implementations, the semiconductor package 1000 uses the package substrate 1000S that includes the stacked silicon capacitor 100 having the solder bump pads SB on both the top surface and the bottom surface thereof. Accordingly, the degree of freedom in circuit design is increased while increasing electrostatic capacity.

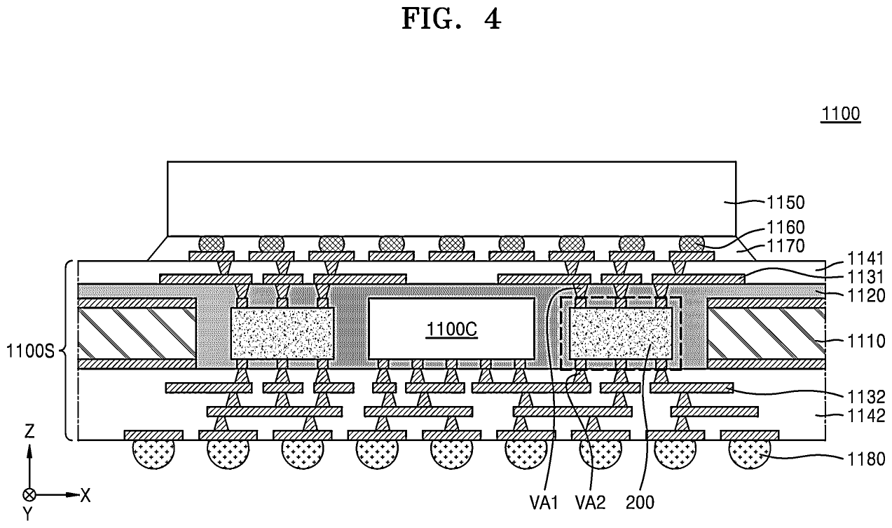

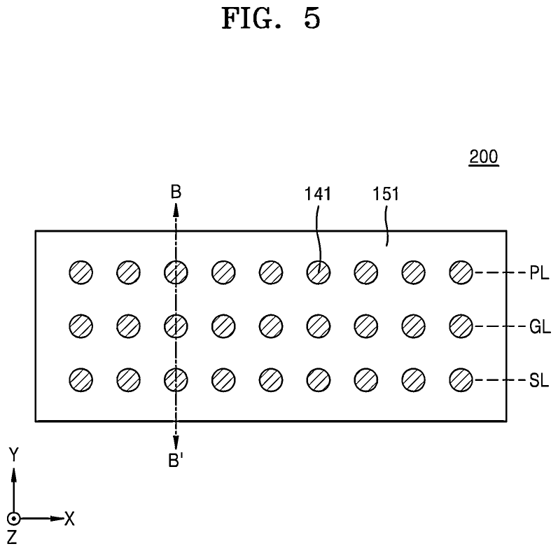

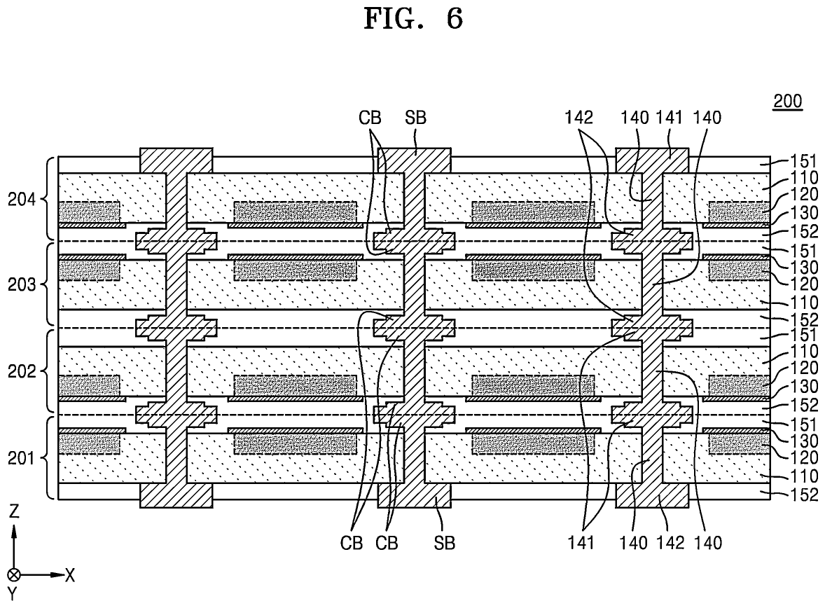

FIG. 4 is a cross-sectional view of main components of an example of a semiconductor package according to some implementations. FIG. 5 is an enlarged plan view of an example of a silicon capacitor of FIG. 4 according to some implementations. FIG. 6 is a cross-sectional view taken along a line B-B′ of FIG. 5 according to some implementations.

Most of components constituting semiconductor package 1100, as described below, and materials constituting the components may be substantially the same as, or similar to, those described above in FIGS. 1 to 3. Accordingly, for convenience of explanation, descriptions below will focus on differences from the semiconductor package 1000 described above.

In FIGS. 4 to 6, the semiconductor package 1100 includes a redistribution structure 1100S in which a silicon capacitor 200 is disposed, a semiconductor chip 1150 mounted on the redistribution structure 1100S, and an external connection terminal 1180 attached below the redistribution structure 1100S.

In some implementations, the semiconductor package 1100 may have a package-on-package (POP) structure. For example, the semiconductor package 1100 may be a fan-out semiconductor package in which the horizontal width and the horizontal area of the redistribution structure 1100S are greater than the horizontal width and the horizontal area of the semiconductor chip 1150. According to some implementations, the semiconductor package 1100 may be a Fan Out Wafer Level Package (FOWLP) or a Fan Out Panel Level Package (FOPLP).

The redistribution structure 1100S may include active elements, such as an internal semiconductor chip 1100C, and passive elements, such as the silicon capacitor 200, may include conductive material layers, such as the upper redistribution layer 1131 and the lower redistribution layer 1132, and may include insulation material layers, such as a core base 1110, a core insulation layer 1120, an upper redistribution insulation layer 1141, and a lower redistribution insulation layer 1142.

In the redistribution structure 1100S, the internal semiconductor chip 1100C and the silicon capacitor 200 may be arranged in the cavity of the core base 1110, an upper redistribution layer 1131 may be formed on the core base 1110, and a lower redistribution layer 1132 may be formed below the core base 1110. Also, an external connection terminal 1180 may be attached below the lower redistribution layer 1132.

Although the redistribution structure 1100S is shown to include one internal semiconductor chip 1100C and two silicon capacitors 200 that are embedded in the cavity of the core base 1110, the redistribution structure 1100S is not limited thereto, and the internal semiconductor chip 1100C and the silicon capacitors 200 may be embedded at regular intervals in the redistribution structure 1100S.

The core insulation layer 1120 may be disposed on each of the top surface and the bottom surface of the core base 1110 in which the internal semiconductor chip 1100C and the silicon capacitors 200 are embedded. The core insulation layer 1120 may include an insulation material. The upper vertical via VA1 and the lower vertical via VA2 electrically connected to the upper redistribution layer 1131 and the lower redistribution layer 1132 may be arranged in the core insulation layer 1120. Also, the upper vertical via VA1 and the lower vertical via VA2 may be connected to the top surface and the bottom surface of the silicon capacitor 200 embedded in the core base 1110 and electrically interconnect the upper redistribution layer 1131 and the lower redistribution layer 1132.

In some implementations, in the semiconductor package 1100, the upper redistribution layer 1131 and the lower redistribution layer 1132 may electrically interconnect the semiconductor chip 1150 and the external connection terminal 1180 by using wires in the silicon capacitor 200.

An internal connection terminal 1160 may be disposed between the semiconductor chip 1150 and the redistribution structure 1100S. For example, the internal connection terminal 1160 may be a solder ball or a micro bump. In other words, the semiconductor chip 1150 and the upper redistribution layer 1131 of the redistribution structure 1100S may be electrically connected to each other through the internal connection terminal 1160.

An underfill 1170 may be formed between the semiconductor chip 1150 and the redistribution structure 1100S. In some cases, the underfill 1170 may be omitted, and an MUF process may be used instead.

In the semiconductor package 1100, the silicon capacitor 200 may have a stacked structure in which N (N is an integer equal to or greater than 2) substrate structures are electrically connected to each other. In some implementations, the silicon capacitor 200 may have a stacked structure of four substrate structures 201, 202, 203, and 204. However, the number of the plurality of substrate structures 201, 202, 203, and 204 is not limited thereto.

The plurality of substrate structures 201, 202, 203, and 204 may each include the silicon substrate 110, the capacitor structure 120, the via electrode 140 penetrating through the silicon substrate 110 around the capacitor structure 120, the upper bump pad 141 disposed on the via electrode 140, and the lower bump pad 142 disposed below the via electrode 140. The upper insulation layer 151 may be disposed around the upper bump pad 141, and the lower insulation layer 152 may be disposed around the lower bump pad 142.

According to some implementations, in the plurality of substrate structures 201, 202, 203, and 204, the upper bump pad 141 and the lower bump pad 142 of neighboring silicon substrates 110 facing each other may be bonded to each other, e.g., through direct bonding. For example, in the silicon capacitor 200, the upper bump pad 141 located at the top of the plurality of substrate structures 201, 202, 203, and 204 and the lower bump pad 142 located at the bottom of the plurality of substrate structures 101 and 102 may be solder bump pads SB, and the remaining upper bump pads 141 and the remaining lower bump pads 142 may be copper bump pads CB. In other words, the remaining upper bump pads 141 and the remaining lower bump pads 142 may be bonded to each other, e.g., through Cu-to-Cu direct bonding.

Additionally, the via electrode 140 may be disposed on each of the silicon substrates 110, and the via electrode 140 may be positioned between capacitor structures 120. Here, the via electrode 140 may perform the function of at least one from among a power line PL, a ground line GL, and a signal line SL. Accordingly, the upper redistribution layer 1131 and the lower redistribution layer 1132 may be electrically connected to each other through the upper vertical via VA1 contacting the top surface of the silicon capacitor 100 and the lower vertical via VA2 contacting the bottom surface of the silicon capacitor 200.

Structurally, the capacitor structure 120 may be disposed adjacent to the top surface of the silicon substrate 110, and the capacitor structures 120 may be arranged in a mirror-symmetrically around the upper insulation layer 151 and the lower insulation layer 152 arranged between the silicon substrates 110 adjacent to each other in the plurality of substrate structures 201, 202, 203, and 204. According to some implementations, the plurality of capacitor structures 120 may be arranged on each of the silicon substrates 110 in horizontal directions (X direction and Y directions). Also, an electrode line 130 may be disposed on the capacitor structure 120. The electrode line 130 may be connected to an upper electrode and a lower electrode constituting the capacitor structure 120.

In some implementations, the semiconductor package 1100 includes a stacked silicon capacitor 200 including the plurality of substrate structures 201, 202, 203, and 204. Accordingly, the silicon capacitor 200 has about four times the electrostatic capacity and lower equivalent series resistance (ESR) characteristic as compared to a typical single-layer silicon capacitor.

Additionally, in the semiconductor package 1100, the upper redistribution layer 1131 and the lower redistribution layer 1132 may electrically interconnect the semiconductor chip 1150 and the external connection terminal 1180 by using wires inside the silicon capacitor 200, and thus the degree of freedom in circuit design in the redistribution structure 1100S may be significantly increased.

The semiconductor package 1100 uses the redistribution structure 1100S including the stacked silicon capacitor 200 having the solder bump pads SB on both the top surface and the bottom surface thereof, and increases the degree of freedom in circuit design while increasing electrostatic capacity.

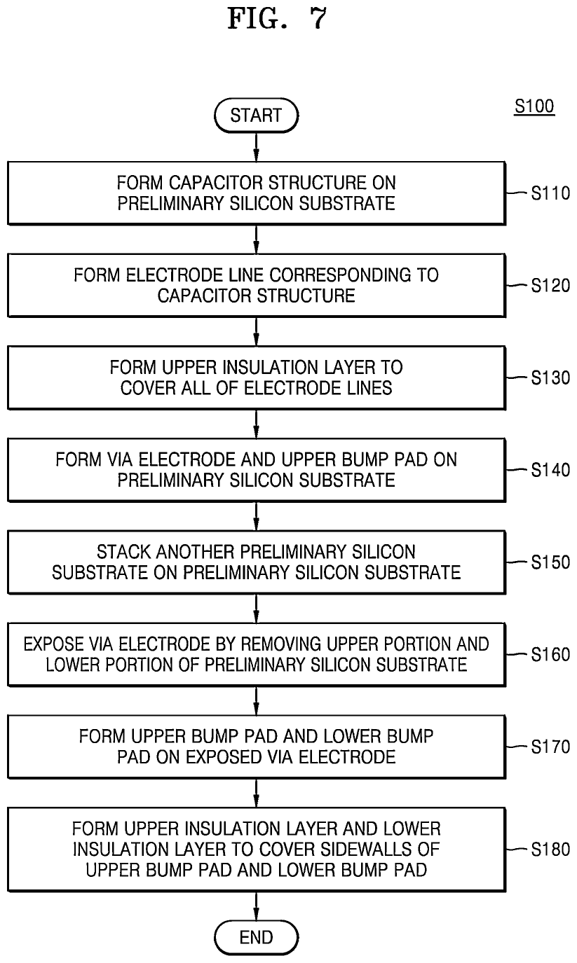

FIG. 7 is a flowchart of an example of a method of manufacturing a silicon capacitor according to some implementations. In FIG. 7, a method S100 of manufacturing a silicon capacitor may include operations S110 to S180.

In some implementations, particular operations may be performed in an order different from that described below. For example, two successively described operations may be performed substantially and simultaneously or may be performed in an order opposite to the order described below.

The method S100 of manufacturing a silicon capacitor may include a first operation S110 of forming a capacitor structure on a preliminary silicon substrate, a second operation S120 of forming an electrode line corresponding to the capacitor structure, a third operation S130 of forming an upper insulation layer to cover all of electrode lines, a fourth operation S140 of forming a via electrode and a upper bump pad on a preliminary silicon substrate, a fifth operation S150 of one preliminary silicon substrate on another preliminary silicon substrate, a sixth operation S160 of exposing the via electrode by removing the upper portion and the lower portion of each of the preliminary silicon substrates, a seventh operation S170 of forming an upper bump pad and a lower bump pad on the exposed via electrode, and an eighth operation S180 of forming an upper insulation layer and a lower insulation layer to cover the sidewalls of the upper bump pad and the lower bump pad.

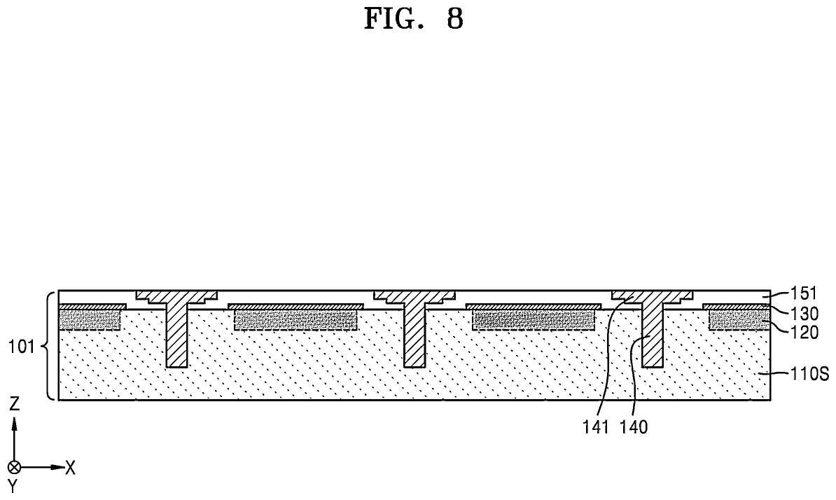

The technical features of each of first to eighth operations S110 to S180 are described below in detail with reference to FIGS. 8 to 12.

FIGS. 8 to 12 are cross-sectional views showing an example of a method of manufacturing a silicon capacitor according to some implementations. In FIG. 8, to form one substrate structure 101, a preliminary silicon substrate 110S is prepared. For example, the preliminary silicon substrate 110S may be a semiconductor wafer containing silicon (Si). The diameter of the preliminary silicon substrate 110S may correspond to the diameter of a wafer on which a semiconductor process is performed and may be, for example, about 300 millimeters (12 inches). However, the preliminary silicon substrate 110S is not limited thereto.

Next, the capacitor structure 120 may be formed on the preliminary silicon substrate 110S. In some implementations, the capacitor structure 120 may be formed as a buried type disposed in the shape of a trench structure inside the preliminary silicon substrate 110S. According to some implementations, the capacitor structure 120 may be formed as a protruding type disposed in the shape of a pillar structure on top of the preliminary silicon substrate 110S. According to some implementations, the plurality of capacitor structures 120 may be arranged on the preliminary silicon substrate 110S in horizontal directions (X direction and Y directions).

Next, the electrode line 130 corresponding to the capacitor structure 120 may be formed on the top surface of the preliminary silicon substrate 110S. The electrode line 130 may be connected to an upper electrode and a lower electrode constituting the capacitor structure 120.

Next, the upper insulation layer 151 may be formed to cover both the top surface of the preliminary silicon substrate 110S and the electrode line 130. The upper insulation layer 151 may include, for example, silicon oxide, silicon nitride, or silicon oxynitride, but is not limited thereto.

Next, the via electrode 140, which is formed around the capacitor structure 120 and extends in the vertical direction (Z direction) from the upper insulation layer 151 and the preliminary silicon substrate 110S, is formed, and the upper bump pad 141 may be formed on the top of via electrode 140. Accordingly, the upper insulation layer 151 may be disposed around the upper bump pad 141. Through this process, one substrate structure 101 may be formed.

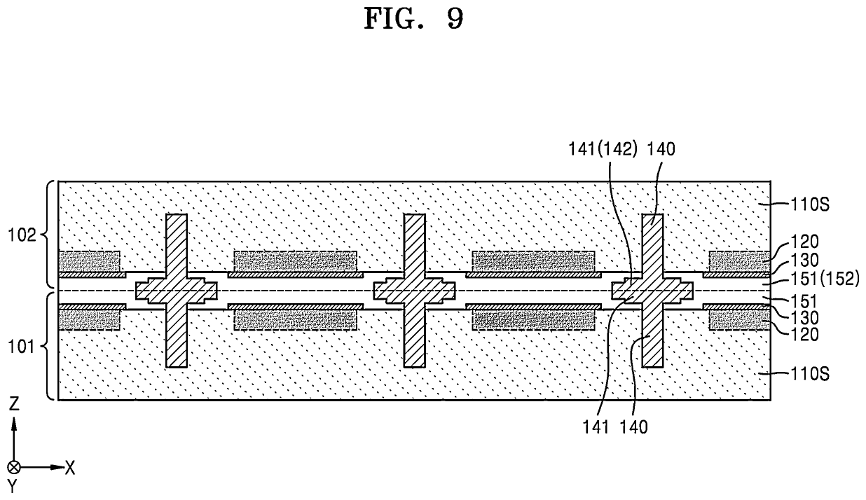

In FIG. 9, another substrate structure 102 may be stacked on the substrate structure 101. The substrate structure 101 and the other substrate structures 102 may constitute the plurality of substrate structures 101 and 102. The substrate structure 101 and the other substrate structure 102 may have substantially the same shape. Here, in the other substrate structure 102, the upper bump pad 141 may be referred to as the lower bump pad 142 according to the position of the substrate structure 102 shown in the drawings. In the plurality of substrate structures 101 and 102, the upper bump pad 141 and the lower bump pad 142 of neighboring preliminary silicon substrates 110S facing each other may be bonded to each other, e.g., through Cu-to-Cu direct bonding.

The capacitor structure 120 may be disposed adjacent to the top surface of the preliminary silicon substrate 110S, and the capacitor structures 120 may be arranged in a mirror-symmetrically around the upper insulation layer 151 and the lower insulation layer 152 formed between the preliminary silicon substrates 110S adjacent to each other in the plurality of substrate structures 101 and 102.

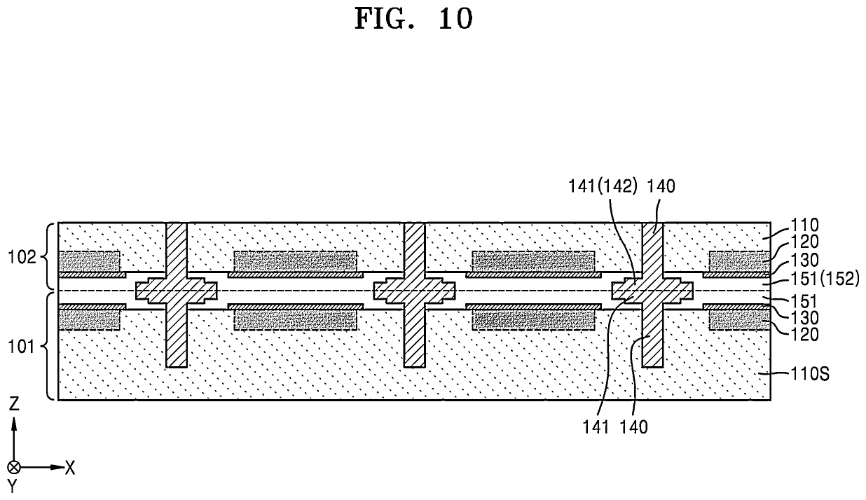

In FIG. 10, the upper portion of the preliminary silicon substrate 110S (refer to FIG. 9) of the other substrate structure 102 may be removed to expose the via electrode 140. A removal process to reduce the thickness of the preliminary silicon substrate 110S (in FIG. 9) may include a process of exposing the top surface of the via electrode 140 by alternately performing a grinding process and a wet etching process. Accordingly, after a portion of the preliminary silicon substrate 110S (in FIG. 9) is removed, the top surface of the silicon substrate 110 may become closer to the capacitor structure 120.

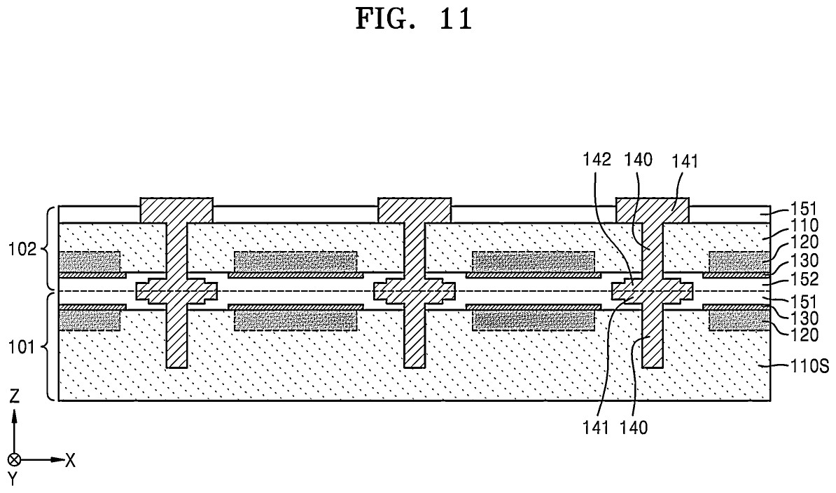

In FIG. 11, the upper bump pad 141 may be formed on the via electrode 140 in the other substrate structure 102. Next, the upper insulation layer 151 may be formed to cover the top surface of the silicon substrate 110 and the sidewall of the via electrode 140. The upper insulation layer 151 may include, for example, silicon oxide, silicon nitride, or silicon oxynitride, but is not limited thereto. Accordingly, the upper insulation layer 151 may be disposed around the upper bump pad 141. Through the process, the other substrate structure 102 may be completed.

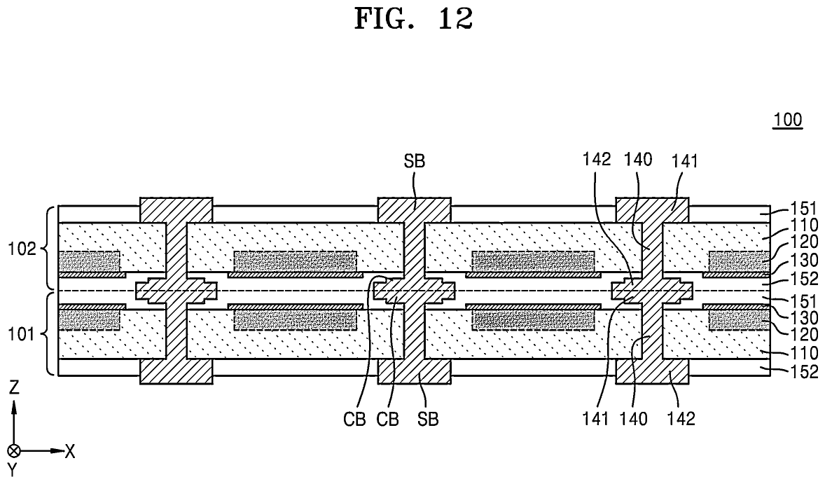

In FIG. 12, the lower portion of the preliminary silicon substrate 110S (in FIG. 11) of the substrate structure 101 may be removed to expose the via electrode 140. Next, the lower bump pad 142 may be formed at the bottom of the via electrode 140 in the substrate structure 101. Then, the lower insulation layer 152 may be formed to cover the bottom surface of the silicon substrate 110 and the sidewall of the lower bump pad 142. The lower insulation layer 152 may include, for example, silicon oxide, silicon nitride, or silicon oxynitride, but is not limited thereto. Accordingly, the lower insulation layer 152 may be disposed around the lower bump pad 142. Through this process, one substrate structure 101 may be completed.

Through the manufacturing process described above, the silicon capacitor 100 may be formed. In some implementations, the silicon capacitor 200 (in FIG. 6) may be formed using a different process.

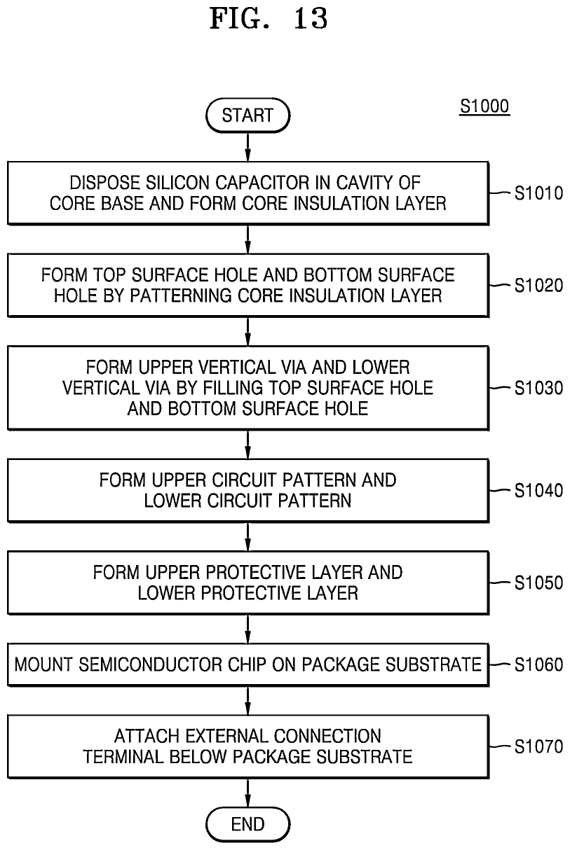

FIG. 13 is a flowchart of an example of a method of manufacturing a semiconductor package, according to some implementations. In FIG. 13, a method S1000 of manufacturing a semiconductor package may include first to seventh operations S1010 to S1070.

In some implementations, particular operations may be performed in an order different from that described below. For example, two successively described operations may be performed substantially and simultaneously or may be performed in an order opposite to the order described below.

The method S1000 of manufacturing a semiconductor package may include a first operation S1010 of placing a silicon capacitor in a cavity of a core base and forming a core insulation layer, a second operation S1020 of forming a top surface hole and a bottom surface hole by patterning the core insulation layer, a third operation S1030 of filling the top surface hole and the bottom surface hole to form an upper vertical via and a lower vertical via, a fourth operation S1040 of forming an upper circuit pattern and a lower circuit pattern, a fifth operation S1050 of forming an upper protective layer and a lower protective layer, a sixth operation S1060 of mounting a semiconductor chip on a package substrate, and a seventh operation S1070 of attaching an external connection terminal to the bottom of the package substrate.

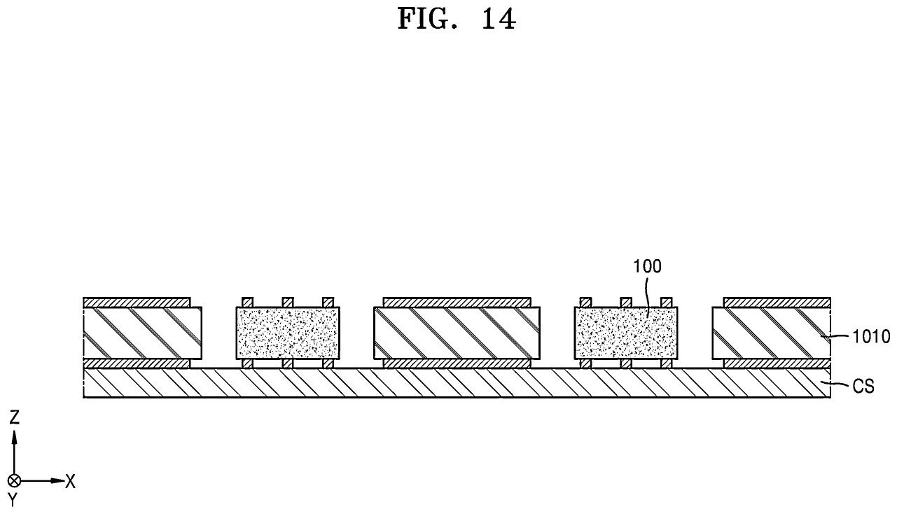

The technical features of each of first to seventh operations S1010 to S1070 are described below in detail with reference to FIGS. 14 to 18.

FIGS. 14 to 18 are cross-sectional views showing an example of a method of manufacturing a semiconductor package according to some implementations. In FIG. 14, to form a PCB as a wiring structure, a carrier substrate CS is prepared. In some implementations, the core base 1010 having a cavity may be disposed on the carrier substrate CS. A cavity may be formed in the core base 1010 in the form of a via hole, and the cavity may be formed through laser processing or drilling using CNC.

Next, the silicon capacitor 100 may be placed in the cavity of the core base 1010. Although two silicon capacitors 100 are shown to be embedded into the cavity of the core base 1010, the number of silicon capacitors 100 is not limited thereto. The core base 1010 may include an insulation material. However, the core base 1010 may also include a metal material, such as aluminum, to improve heat dissipation efficiency.

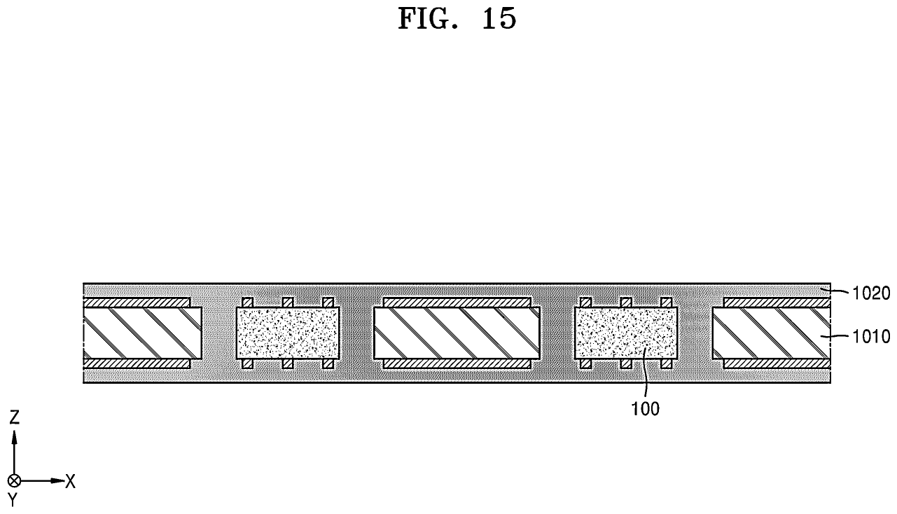

In FIG. 15, the core insulation layer 1020 may be formed to surround the core base 1010 and the silicon capacitor 100. In some implementations, the core insulation layer 1020 may be disposed on each of the top surface and the bottom surface of the core base 1010 in which the silicon capacitor 100 is embedded. The core insulation layer 1020 may include an insulation material. In the process of forming the core insulation layer 1020, the carrier substrate CS (refer to FIG. 14) may be removed.

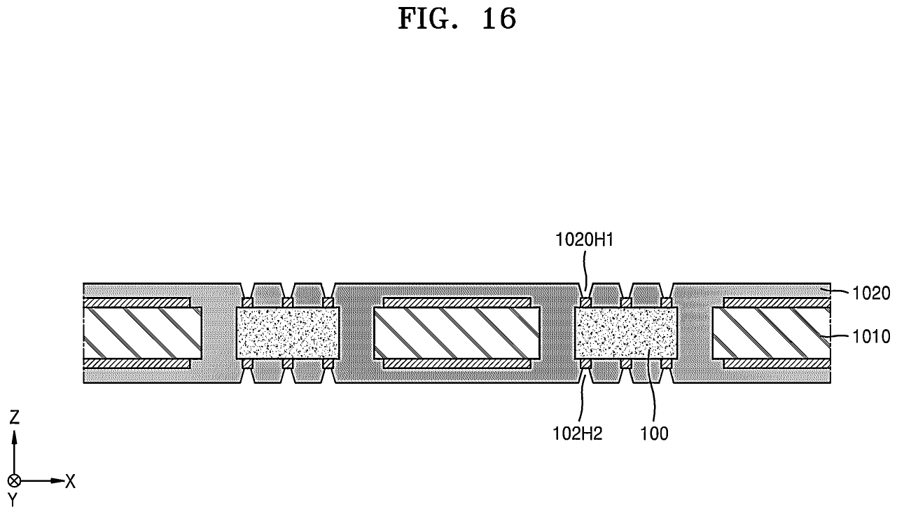

In FIG. 16, the top surface and the bottom surface of the core insulation layer 1020 may be patterned to form a top surface hole 1020H1 and a bottom surface hole 1020H2 that expose solder bump pads of the silicon capacitor 100.

As described above, the silicon capacitor 100 may include solder bump pads on the top surface and the bottom surface of the silicon capacitor 100 and may simultaneously serve as a wire through the via electrode 140 (refer to FIG. 3) inside the silicon capacitor 100. To this end, the top surface hole 1020H1 exposing solder bump pads formed on the top surface of the silicon capacitor 100 and the bottom surface hole 1020H2 exposing solder bump pad formed on the bottom surface of the silicon capacitor 100 may be formed in the core insulation layer 1020.

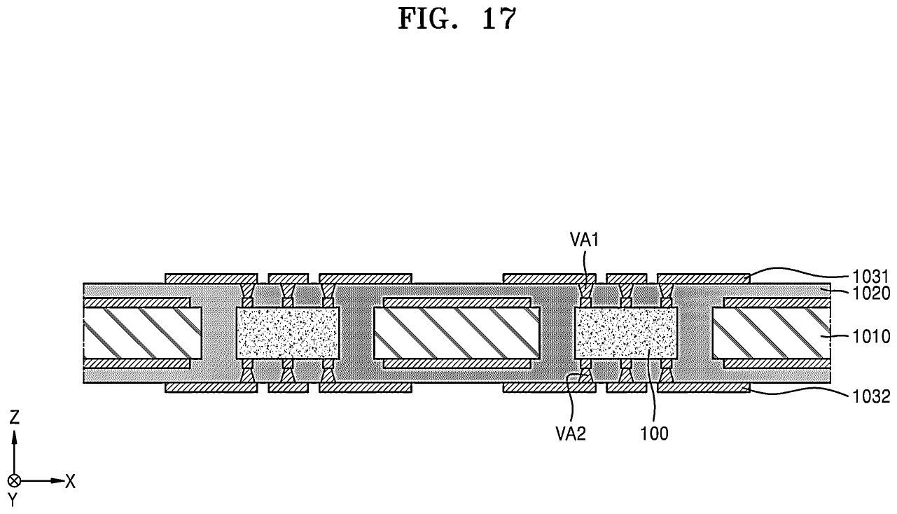

In FIG. 17, the top surface hole 1020H1 (refer to FIG. 16) and the bottom surface hole 1020H2 (refer to FIG. 16) formed in the core insulation layer 1020 may be filled to form the upper vertical via VA1 and the lower vertical via VA2. The upper vertical via VA1 may be in direct contact with the solder bump pad formed on the top surface of the silicon capacitor 100, and the lower vertical via VA2 may be in direct contact with the solder bump pad formed on the bottom surface of the silicon capacitor 100. Next, the upper circuit pattern 1031 electrically connected to the upper vertical via VA1 and the lower circuit pattern 1032 electrically connected to the lower vertical via VA2 may be formed.

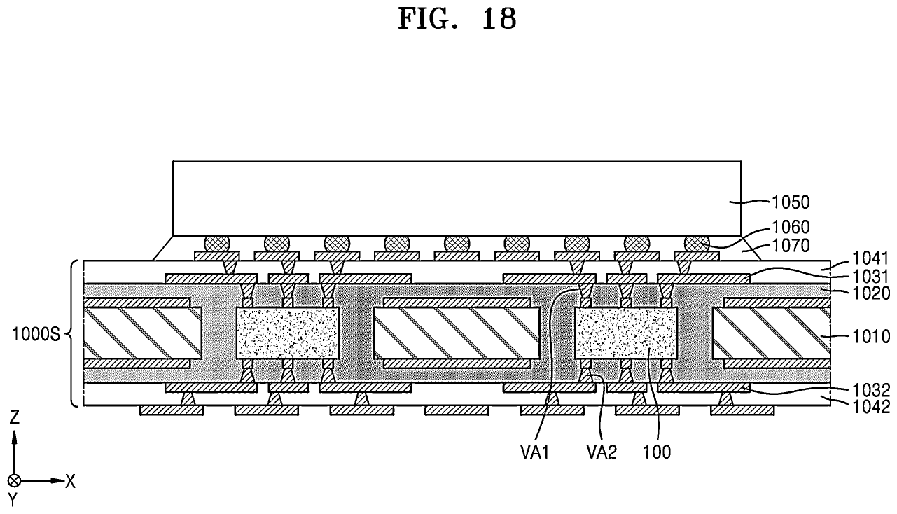

In FIG. 18, the upper protective layer 1041 surrounding the upper circuit pattern 1031 and the lower protective layer 1042 surrounding the lower circuit pattern 1032 may be formed. Accordingly, the package substrate 1000S may be formed. In the package substrate 1000S, the silicon capacitor 100 may be placed in a cavity of the core base 1010, an upper circuit pattern 1031 may be formed above the core base 1010, and a lower circuit pattern 1032 may be formed below the core base 1010.

Next, the semiconductor chip 1050 may be mounted on the package substrate 1000S. Here, the internal connection terminal 1060 may be formed between the semiconductor chip 1050 and the package substrate 1000S. Also, the underfill 1070 may be formed between the semiconductor chip 1050 and the package substrate 1000S.

In FIG. 1, the external connection terminal 1080 may be attached below the package substrate 1000S. For example, the semiconductor package 1000 may be mounted by being electrically connected to a module board or a system board of an electronic device through the external connection terminal 1080.

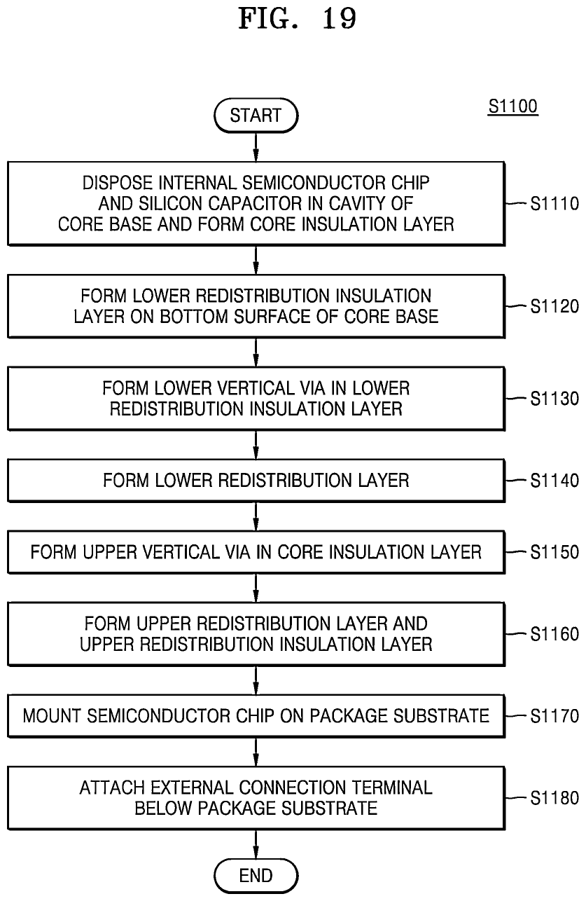

FIG. 19 is a flowchart of an example of a method of manufacturing a semiconductor package according to some implementations. In FIG. 19, a method S1100 of manufacturing a semiconductor package may include first to eighth operations S1110 to S1180.

In some implementations, particular operations may be performed in an order different from that described below. For example, two successively described operations may be performed substantially and simultaneously or may be performed in an order opposite to the order described below.

The method S1100 of manufacturing a semiconductor package may include a first operation S1110 of placing an internal semiconductor chip and a silicon capacitor in a cavity of a core base and forming a core insulation layer, a second operation S1120 of forming a lower redistribution insulation layer on the bottom surface of the core base, a third operation S1130 of forming a lower vertical via in the lower redistribution insulation layer, a fourth operation S1140 of forming a lower redistribution layer, a fifth operation S1150 of forming an upper vertical via in the core insulation layer, a sixth operation S1160 of forming an upper redistribution layer and an upper redistribution insulation layer, a seventh operation S1170 of mounting a semiconductor chip on a redistribution structure, and an eighth operation S1180 of attaching an external connection terminal below the redistribution structure.

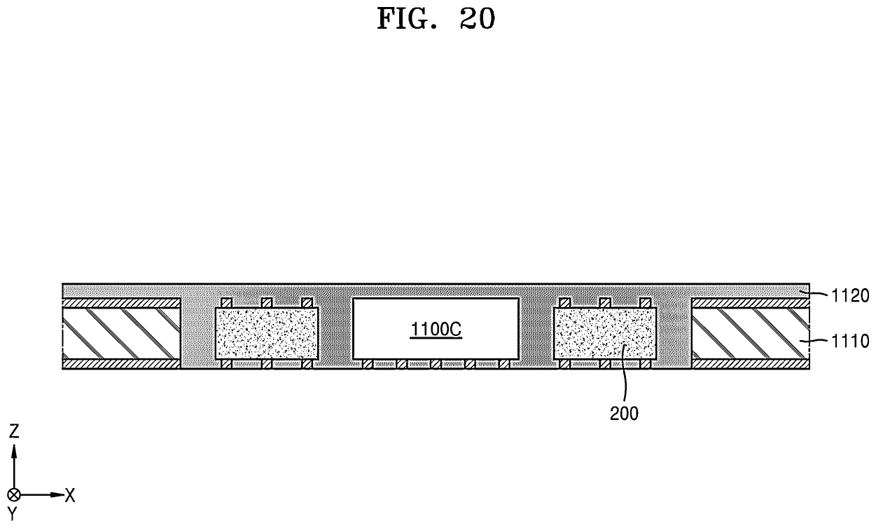

The technical features of first to eighth operations S1110 to S1180 will be described below in detail with reference to FIGS. 20 to 27.

FIGS. 20 to 27 are cross-sectional views showing an examples of a method of manufacturing a semiconductor package according to some implementations. In FIG. 20, to form a redistribution structure as a wiring structure, the core base 1110 is prepared. The core base 1110 having a cavity may be placed. A cavity may be formed in the core base 1110 in the form of a via hole, and the cavity may be formed through laser processing or drilling using CNC.

Next, active devices, such as the internal semiconductor chip 1100C, and passive devices, such as the silicon capacitor 200, may be placed in the cavity of the core base 1110. Although one internal semiconductor chip 1100C and two silicon capacitors 200 are shown embedded in the cavity of the core base 1110, the cavity of the core base 1110 is not limited thereto.

Next, the core insulation layer 1120 may be formed to surround the core base 1110, the internal semiconductor chip 1100C, and the silicon capacitor 200. The core insulation layer 1120 may be formed on the top surface of the core base 1110 in which the internal semiconductor chip 1100C and the silicon capacitors 200 are embedded. The core insulation layer 1120 may include an insulation material.

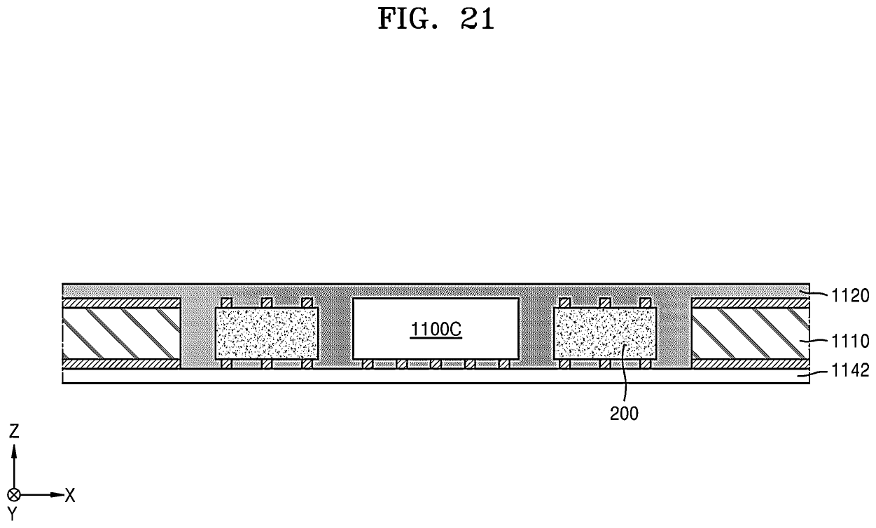

In FIG. 21, the lower redistribution insulation layer 1142 may be formed on the bottom surface of the core base 1110. The lower redistribution insulation layer 1142 may be formed to be contact with the bottom surface of the core base 1110, the bottom surface of the core insulation layer 1120, the bump pad of the internal semiconductor chip 1100C, and the solder bump pad of the silicon capacitor 200. The lower redistribution insulation layer 1142 may include, for example, silicon oxide, silicon nitride, or silicon oxynitride, but is not limited thereto.

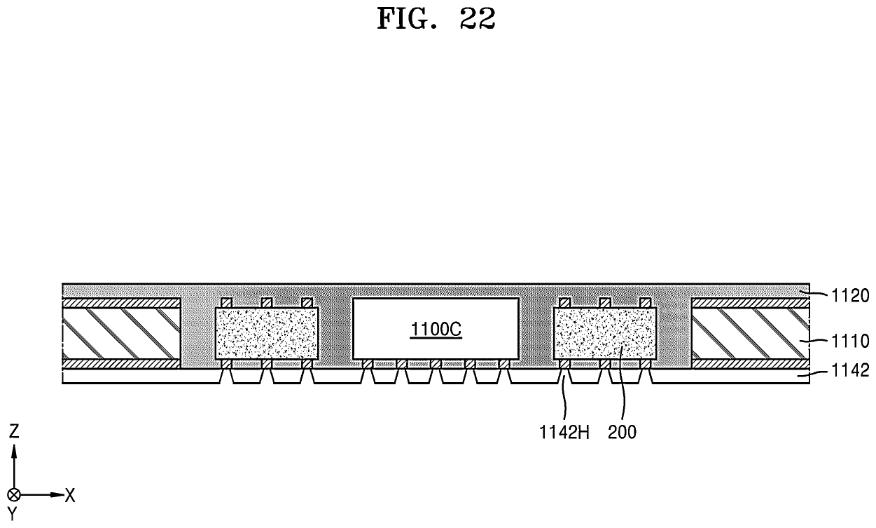

In FIG. 22, the lower redistribution insulation layer 1142 may be patterned to form a lower via hole 1142H1 exposing the bump pad of the internal semiconductor chip 1100C and the solder bump pad of the silicon capacitor 200. As described above, the silicon capacitor 200 may include solder bump pads on the top surface and the bottom surface of the silicon capacitor 200 and may simultaneously serve as a wire through the via electrode 240 (in FIG. 6) inside the silicon capacitor 100. To this end, first, the lower via hole 1142H1 exposing the solder bump pad formed on the bottom surface of the silicon capacitor 200 may be formed in the lower redistribution insulation layer 1142.

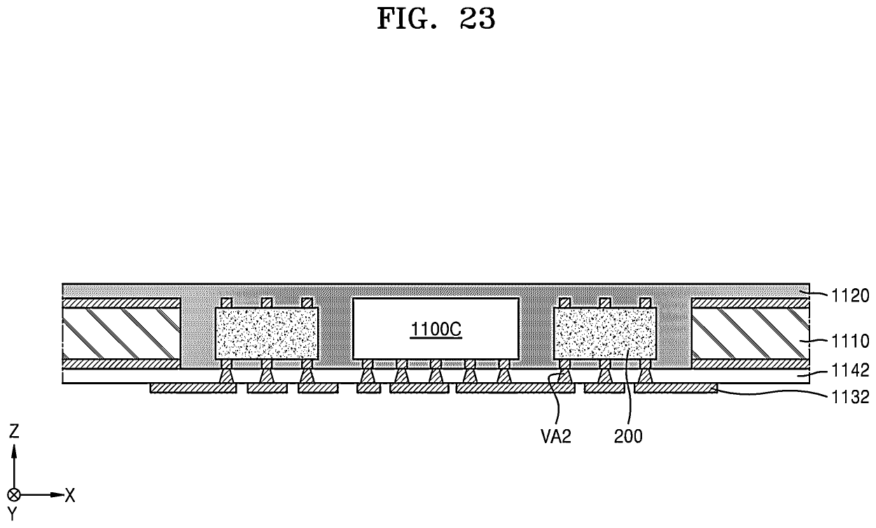

In FIG. 23, the lower via hole 1142H1 (refer to FIG. 22) formed in the lower redistribution insulation layer 1142 may be filled to form the lower vertical via VA2. The lower vertical via VA2 may contact the bump pad of the internal semiconductor chip 1100C and the solder bump pad formed on the bottom surface of the silicon capacitor 200. In some implementations, the lower vertical via VA2 may directly contact the bump pad of the internal semiconductor chip 1100C. Next, a portion of the lower redistribution layer 1132 electrically connected to the lower vertical via VA2 may be formed.

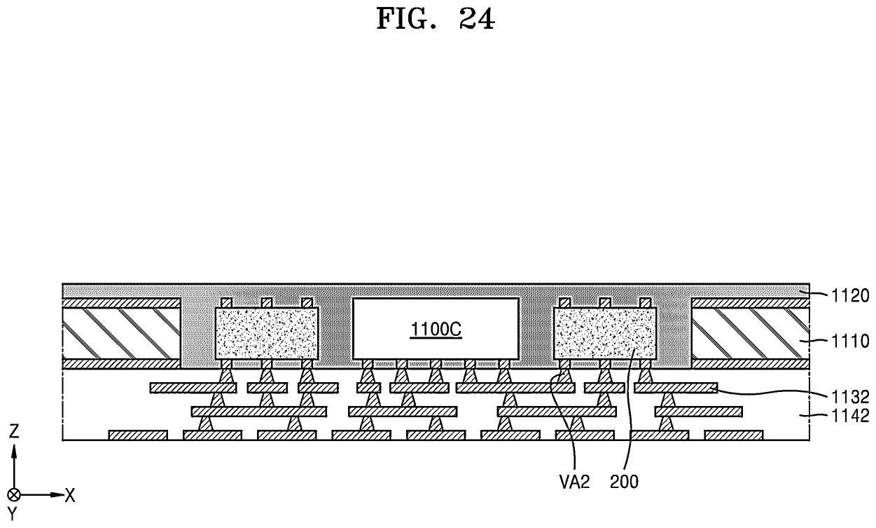

In FIG. 24, the lower redistribution layer 1132 may be formed to include a plurality of layers, and the lower redistribution insulation layer 1142 may be formed to include a plurality of layers. Although the lower redistribution layer 1132 is shown to include three layers, the lower redistribution layer 1132 is not limited thereto. Also, a conductive via may be formed inside the lower redistribution insulation layer 1142 to interconnect the plurality of layers included in the lower redistribution layer 1132 in the vertical direction (Z direction).

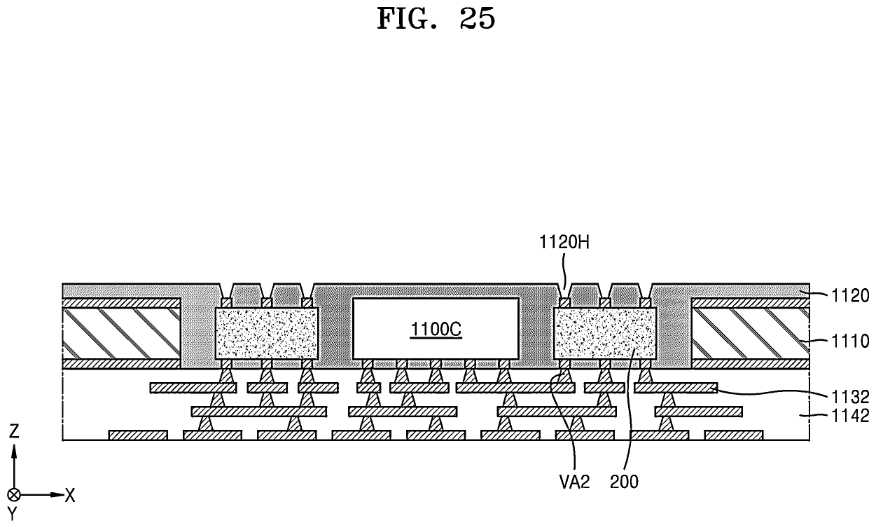

In FIG. 25, the top surface of the core insulation layer 1120 may be patterned to form a top surface hole 1120H1 exposing the solder bump pad of the silicon capacitor 200. As described above, the silicon capacitor 200 may include solder bump pads on the top surface and the bottom surface of the silicon capacitor 200 and may simultaneously serve as a wire through the via electrode 240 (in FIG. 6) inside the silicon capacitor 100. To this end, the top surface hole 1120H1 exposing the solder bump pad formed on the top surface of the silicon capacitor 200 may be formed in the core insulation layer 1120.

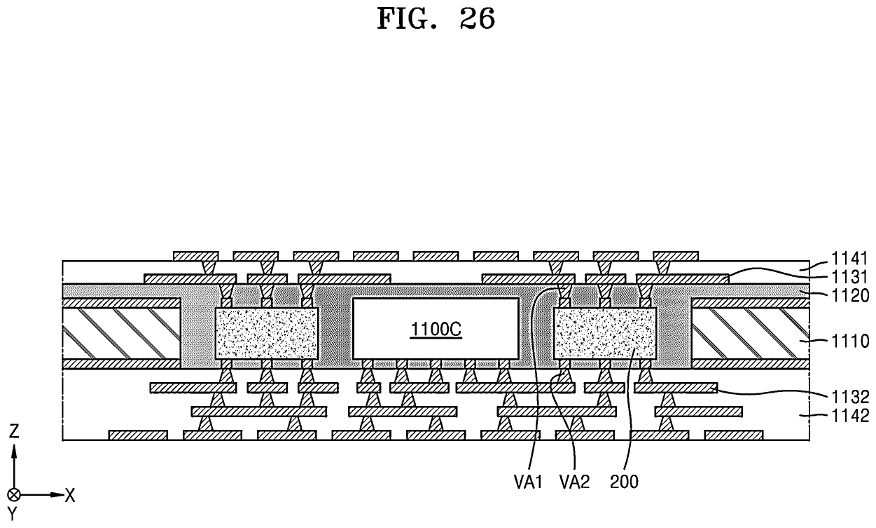

In FIG. 26, the top surface hole 1120H1 (refer to FIG. 25) formed in the core insulation layer 1120 may be filled to form the upper vertical via VA1. The upper vertical via VA1 may contact the solder bump pad formed on the top surface of the silicon capacitor 200.

Next, the upper redistribution layer 1131 electrically connected to the upper vertical via VA1 and the upper redistribution insulation layer 1141 surrounding the upper redistribution layer 1131 may be formed. Accordingly, the redistribution structure 1100S may be formed. In the redistribution structure 1100S, the internal semiconductor chip 1100C and the silicon capacitor 200 may be arranged in the cavity of the core base 1110, an upper redistribution layer 1131 may be formed on the core base 1110, and the lower redistribution layer 1132 may be formed below the core base 1110.

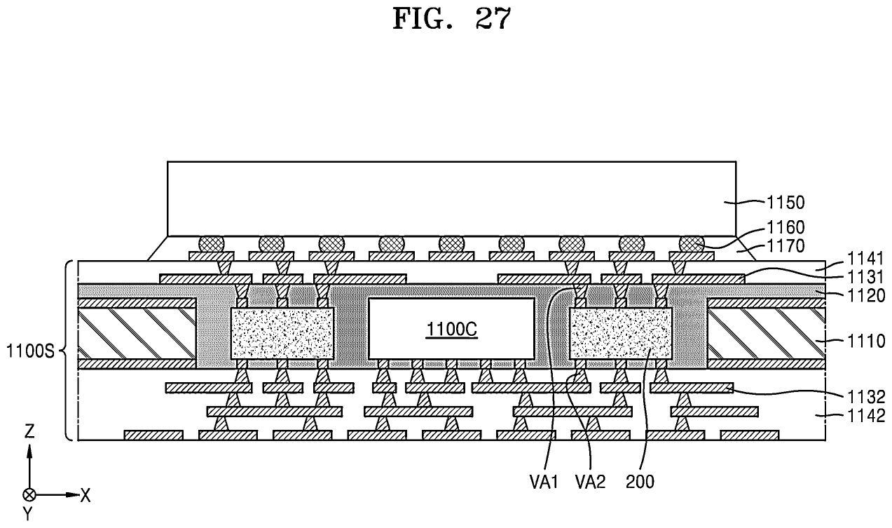

In FIG. 27, the semiconductor chip 1150 may be mounted on the redistribution structure 1100S. Here, the internal connection terminal 1160 may be formed between the semiconductor chip 1150 and the redistribution structure 1100S. Also, the underfill 1170 may be formed between the semiconductor chip 1150 and the redistribution structure 1100S.

In FIG. 4, the external connection terminal 1180 may be attached below the redistribution structure 1100S. For example, the semiconductor package 1100 may be mounted by being electrically connected to a module board or a system board of an electronic device through the external connection terminal 1180.

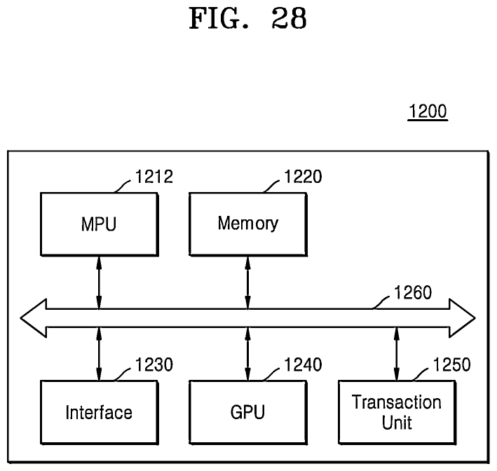

FIG. 28 is a diagram schematically showing an example of a configuration of a semiconductor package according to some implementations. In FIG. 28, a semiconductor package 1200 may include a microprocessor 1210, a memory 1220, an interface 1230, a graphics processing unit 1240, functional blocks 1250, and a bus 1260 connecting them to one another. The semiconductor package 1200 may include both the microprocessor 1210 and the graphics processing unit 1240 or may include only one of them.

The microprocessor 1210 may include a core and a cache. For example, the microprocessor 1210 may include multi-cores. Cores of the multi-cores may have performance same as or different from one another. Also, the core of the multi-cores may be activated at the same time or may be activated at different times.

The memory 1220 may store results processed by the functional blocks 1250 under the control of the microprocessor 1210. The interface 1230 may exchange information or signals with external devices. The graphics processing unit 1240 may perform graphic functions. For example, the graphics processing unit 1240 may execute a video codec or process 3D graphics. The functional blocks 1250 may perform various functions. For example, when the semiconductor package 1200 is an application processor used in a mobile device, some of the functional blocks 1250 may perform a communication function.

The semiconductor package 1200 may include the semiconductor package 1000 and/or the semiconductor package 1100 described above.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A semiconductor package comprising:
a printed circuit board comprising a circuit pattern and a silicon capacitor connected to the circuit pattern;
a semiconductor chip on the printed circuit board; and
an external connection terminal below the printed circuit board,
wherein the silicon capacitor includes a stacked structure of a plurality of substrate structures,
wherein the plurality of substrate structures comprises, respectively:
silicon substrates;
capacitor structures;
via electrodes, each extending through a respective one of the silicon substrates around a respective one of the capacitor structures;
upper bump pads on a top of the via electrodes, respectively; and
lower bump pads below the via electrodes, respectively,
wherein neighboring silicon substrates in the plurality of substrate structures are bonded to each other through a respective one of the upper bump pads and a respective one of the lower bump pads that face each other.

2. The semiconductor package of claim 1, wherein the circuit pattern is connected to each of a top surface and a bottom surface of the silicon capacitor through vertical vias.

3. The semiconductor package of claim 2, wherein, in the plurality of substrate structures, a first upper bump pad of the upper bump pads and a first lower bump pad of the lower bump pads are solder bump pads, the first upper bump pad being located at a top of a first via electrode of the via electrodes and the first lower bump pad being located at a bottom of the first via electrode of the via electrodes, and
wherein, in the plurality of substrate structures, one or more remaining upper bump pads of the upper bump pads and one or more remaining lower bump pads of the lower bump pads are copper bump pads.

4. The semiconductor package of claim 3, wherein the vertical vias contact a first solder bump pad of the solder bump pads and a second solder bump pad of the solder bump pads, the first solder bump pad being located at a top of a second via electrode of the via electrodes and the second solder bump pad being located at a bottom of the second via electrode of the via electrodes and
wherein the vertical vias are electrically connected to the via electrode.

5. The semiconductor package of claim 1, wherein the capacitor structure includes a trench-like structure inside the silicon substrate.

6. The semiconductor package of claim 1, wherein the capacitor structure includes a pillar-like structure on top of the silicon substrate.

7. The semiconductor package of claim 1, wherein the capacitor structures are arranged in horizontal directions on the silicon substrate.

8. The semiconductor package of claim 7,
wherein a plurality of via electrodes are arranged on the silicon substrate, and
wherein the plurality of via electrode are located between the capacitor structures adjacent to each other.

9. The semiconductor package of claim 8, wherein the plurality of via electrodes are configured as at least one of a power line, a ground line, or a signal line.

10. The semiconductor package of claim 1,
wherein the capacitor structures are disposed adjacent to top surfaces of the silicon substrates, and
wherein the capacitor structures are arranged mirror-symmetrically around an insulation layer disposed between neighboring silicon substrates of the silicon substrates in the plurality of substrate structures.

11. A semiconductor package comprising:
a redistribution structure comprising a redistribution layer and a silicon capacitor connected to the redistribution layer;
a semiconductor chip on the redistribution structure; and
an external connection terminal below the redistribution structure,
wherein the silicon capacitor includes a stacked structure of a plurality of substrate structures,
wherein the plurality of substrate structures respectively comprises:
silicon substrates;
capacitor structures;
via electrodes, each extending through a respective one of the silicon substrates around a respective one of the capacitor structures;
upper bump pads on a top of the via electrodes, respectively; and
lower bump pads below the via electrode, respectively, and,
wherein neighboring silicon substrates in the plurality of substrate structures are bonded to each other through a respective one of the upper bump pads and a respectively one of the lower bump pads that face each other.

12. The semiconductor package of claim 11, wherein the redistribution layer comprises:
an upper redistribution layer disposed between the silicon capacitor and the semiconductor chip; and
a lower redistribution layer disposed between the silicon capacitor and the external connection terminal.

13. The semiconductor package of claim 12, wherein, in the plurality of substrate structures, a first bump pad of the upper bump pads and a first lower bump pad of the lower bump pads are solder bump pads, the first upper bump pad being located the top of a first of the via electrodes and the first lower bump pad being located at a bottom of the first of the via electrodes, and
wherein, in the plurality of substrate structures, one or more remaining upper bump pads of the upper bump pads and one or more remaining lower bump pads of the lower bump pads are copper bump pads.

14. The semiconductor package of claim 13,
wherein the solder bump pads located at the top of the first of the via electrodes and the upper redistribution layer are electrically connected through an upper vertical via, and
wherein the solder bump pads located at the bottom of the first of the via electrodes and the lower redistribution layer are electrically connected through a lower vertical via.

15. The semiconductor package of claim 14, wherein at least a portion of the upper redistribution layer is electrically connected to the lower redistribution layer through the silicon capacitor.

16. A semiconductor package, comprising:
at least one silicon capacitor comprising a stacked structure;
two or more substrate structures electrically connected to each other; and
a semiconductor chip mounted on a wiring structure comprising the at least one silicon capacitor, and
wherein the two or more substrate structures respectively comprises:
silicon substrates, each having a first surface and a second surface that faces the first surface;
capacitor structures disposed on the first surface of the silicon substrate;
electrode lines disposed on top of the capacitor structure;
via electrodes, each extending through a respective one of the silicon substrates around a respective one of the capacitor structures;
first insulation layers, each disposed on the first surface of a respective one of the silicon substrates surrounding a first bump pad disposed at a first end of a respective one of the via electrodes; and
second insulation layers, each disposed on the second surface of a respective one of the silicon substrates surrounding a second bump pad disposed at a second end of a respective one of the via electrodes.

17. The semiconductor package of claim 16,
wherein the wiring structure comprises an upper wiring layer disposed above the at least one silicon capacitor and a lower wiring layer disposed below the at least one silicon capacitor, and
wherein the upper wiring layer and the lower wiring layer are electrically connected to each other through the at least one silicon capacitor.

18. The semiconductor package of claim 17, wherein at least one of a power line, a ground line, and a signal line is connected to the upper wiring layer and the lower wiring layer through the at least one silicon capacitor.

19. The semiconductor package of claim 16, wherein, in the two or more substrate structures, the first bump pad and the second bump pad of neighboring silicon substrates facing each other are copper-to-copper (Cu-to-Cu) bonded to each other, and the first insulation layer and the second insulation layer of the neighboring silicon substrates are bonded to each other.

20. The semiconductor package of claim 19, wherein each via electrode in the two or more substrate structures overlap each other in a vertical direction.
